(19) United States
(12) Patent Application Publication
(10) Pub. No.: US 2026/0076176 A1
(43) Pub. Date: Mar. 12, 2026

(54) SEMICONDUCTOR DEVICE AND MANUFACTURING METHOD THEREOF

(71) Applicant: NANYA TECHNOLOGY CORPORATION, New Taipei City (TW)

(72) Inventor: Cheng Yan JI, New Taipei City (TW)

(21) Appl. No.: 18/827,866

(22) Filed: Sep. 9, 2024

(51) Int. Cl. H01L 23/532; H01L 21/02; H01L 21/762

(52) U.S. Cl. CPC H10W 20/48; H10P 14/6339; H10P 14/6903; H10W 10/014; H10W 10/17

(57) ABSTRACT

A manufacturing method of a semiconductor device includes depositing, using a first atomic layer deposition, a first thin poly silicon layer on an active area, in which the active area includes a trench; depositing, using a second atomic layer deposition, a second thin poly silicon layer on the active area; and depositing, using a chemical vapor deposition, a poly silicon layer on the active area to form a poly silicon structure, in which a gas for the chemical vapor deposition includes disilane, a thickness of the poly silicon layer in a bottom of the trenches is substantially zero.

### BACKGROUND

### Field of Invention

The present disclosure relates to a semiconductor device and a manufacturing method of a semiconductor device.

### Description of Related Art

The semiconductor integrated circuit (IC) industry has experienced exponential growth. Technological advances in IC materials and design have produced generations of ICs where each generation has smaller and more complex circuits than the previous generation. In the manufacturing of DRAM cells, after the etching of active area, a thin poly silicon layer is cover on the array to enlarge the area of the array. However, the process used in the growth of the thin poly silicon layer often cause the growth of the poly silicon at the bottom of the trench, which is a place that is not necessary to grow the poly silicon layer and will have a risk of short.

### SUMMARY

One aspect of the present disclosure provides a manufacturing method of a semiconductor device.

According to one embodiment of the present disclosure, a manufacturing method of a semiconductor device includes depositing, using a first atomic layer deposition, a first thin poly silicon layer on an active area, in which the active area includes a trench; depositing, using a second atomic layer deposition, a second thin poly silicon layer on the active area; and depositing, using a chemical vapor deposition, a poly silicon layer on the active area to form a poly silicon structure, in which a gas for the chemical vapor deposition includes disilane, a thickness of the poly silicon layer in a bottom of the trenches is substantially zero.

In some embodiment of the present disclosure, the manufacturing method of the semiconductor device further includes etching a substrate to form the active area.

In some embodiment of the present disclosure, the manufacturing method of the semiconductor device further includes filling the trenches with a dielectric material to form a shallow trench isolation.

In some embodiment of the present disclosure, a ratio of a thickness of a top portion of a sidewall of the poly silicon structure to a thickness of a top plane of the poly silicon structure is in a range of 0.6 to 0.7.

In some embodiment of the present disclosure, a ratio of a thickness of a middle portion of a sidewall of the poly silicon structure to a thickness of a top plane of the poly silicon structure is in a range of 0.6 to 0.7.

In some embodiment of the present disclosure, a ratio of a thickness of a bottom portion of a sidewall of the poly silicon structure to a thickness of a top plane of the poly silicon structure is in a range of 0.35 to 0.45.

In some embodiment of the present disclosure, a gas used in the first atomic layer deposition includes dichlorosilane.

Another aspect of the present disclosure provides a manufacturing method of a semiconductor device.

According to one embodiment of the present disclosure, a manufacturing method of a semiconductor device includes depositing, using a first atomic layer deposition, a first thin poly silicon layer on an active area, in which the active area includes a trench, a gas used in the first atomic layer deposition includes dichlorosilane; depositing, using a second atomic layer deposition, a second thin poly silicon layer on the active area; and depositing, using a chemical vapor deposition, a poly silicon layer on the active area to form a poly silicon structure, in which a gas for the chemical vapor deposition includes disilane.

In some embodiment of the present disclosure, the manufacturing method of the semiconductor device further includes etching a substrate to form the active area.

In some embodiment of the present disclosure, the manufacturing method of the semiconductor device further includes filling the trenches with a dielectric material to form a shallow trench isolation.

In some embodiment of the present disclosure, a ratio of a thickness of a top portion of a sidewall of the poly silicon structure to a thickness of a top plane of the poly silicon structure is in a range of 0.6 to 0.7.

In some embodiment of the present disclosure, a ratio of a thickness of a middle portion of a sidewall of the poly silicon structure to a thickness of a top plane of the poly silicon structure is in a range of 0.6 to 0.7.

In some embodiment of the present disclosure, a ratio of a thickness of a bottom portion of a sidewall of the poly silicon structure to a thickness of a top plane of the poly silicon structure is in a range of 0.35 to 0.45.

In some embodiment of the present disclosure, a gas used in the second atomic layer deposition includes disilane.

Another aspect of the present disclosure provides a semiconductor device.

According to one embodiment of the present disclosure, a semiconductor device includes a substrate and a poly silicon layer. The substrate includes an active area. The active area includes a trench. The poly silicon layer is located on the active area, in which a thickness of the poly silicon layer gradually shrinks from a top portion of a sidewall of the poly silicon layer to a bottom portion of the sidewall of the poly silicon layer.

In some embodiment of the present disclosure, a thickness of the poly silicon layer on a bottom of the trench is substantially zero.

In some embodiment of the present disclosure, a ratio of a thickness of the top portion of the sidewall of the poly silicon layer to a thickness of a top plane of the poly silicon layer is in a range of 0.6 to 0.7.

In some embodiment of the present disclosure, a ratio of a thickness of a middle portion of the sidewall of the poly silicon layer to a thickness of a top plane of the poly silicon layer is in a range of 0.6 to 0.7.

In some embodiment of the present disclosure, a ratio of a thickness of the bottom portion of the sidewall of the poly silicon layer to a thickness of a top plane of the poly silicon layer is in a range of 0.35 to 0.45.

In some embodiment of the present disclosure, the poly silicon layer is formed by a first atomic layer deposition, a second atomic layer deposition and a chemical vapor deposition.

In the aforementioned embodiments of the present disclosure, since the manufacturing method of the semiconductor device includes a first atomic layer deposition, a second atomic layer deposition and a chemical vapor deposition, the thickness of the poly silicon layer grow by the chemical vapor deposition gradually shrinks from a top portion of a sidewall of the poly silicon layer to a bottom portion of the sidewall of the poly silicon layer, which means no poly silicon is grown at the bottom of the trench, eliminating the possibility of causing short at the bottom of the trench while enlarging the area of the array.

### BRIEF DESCRIPTION OF THE DRAWINGS

FIG. 1 is a flow chart of a manufacturing method of a semiconductor device according to one embodiment of the present disclosure.

FIG. 2 to FIG. 6 are cross-sectional views of intermediate steps of the manufacturing method of the semiconductor device according to one embodiment of the present disclosure.

### DETAILED DESCRIPTION

The embodiments of the present invention can be best understood from the following detailed description and appended claims. It is emphasized that, in accordance with standard practice practices in the industry, various features are not necessarily drawn to scale. In fact, the dimensions of the various features may be arbitrarily enlarged or reduced for clarity of discussion.

The following disclosure provides many different embodiments, or examples, for implementing different features of the provided subject matter. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The terms “about”, “approximately”, or “substantially” used herein include the value and an average of values within an acceptable tolerance range of a specific value determined by one of ordinary skill in the art, in consideration of a specific quantity of measurement and measurement related errors discussed (that is, limitation of a measuring system). For example, “about” may indicate within one or more standard deviation of the value, or within +30%, +20%, +10%, or +5% of the value. Further, for the terms “about”, “approximately”, or “substantially” used herein, a relatively acceptable tolerance range or standard deviation may be selected based on optical properties, etching properties, or other properties, rather than one standard is applied to all properties.

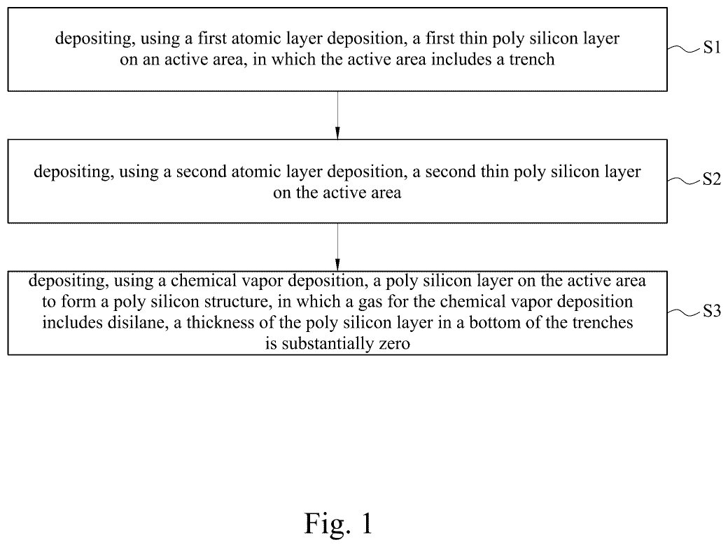

FIG. 1 is a flow chart of a manufacturing method of a semiconductor device according to one embodiment of the present disclosure. Refer to FIG. 1, a manufacturing method of a semiconductor device includes the following steps. First in step S1, depositing, using a first atomic layer deposition, a first thin poly silicon layer on an active area, in which the active area comprises a trench. Thereafter, in step S2, depositing, using a second atomic layer deposition, a second thin poly silicon layer on the active area. Finally, in step S3, depositing, using a chemical vapor deposition, a poly silicon layer on the active area, in which a gas for the chemical vapor deposition comprises disilane, a thickness of the poly silicon layer in a bottom of the trenches is zero.

In some embodiments, the manufacturing method of the semiconductor device is not limited to the steps S1 to S3 mentioned above. For example, in some embodiments, other steps can be further included between two steps of the steps S1 to S3, before step S1, or after step S3. In the following description, at least the above steps are described in detail.

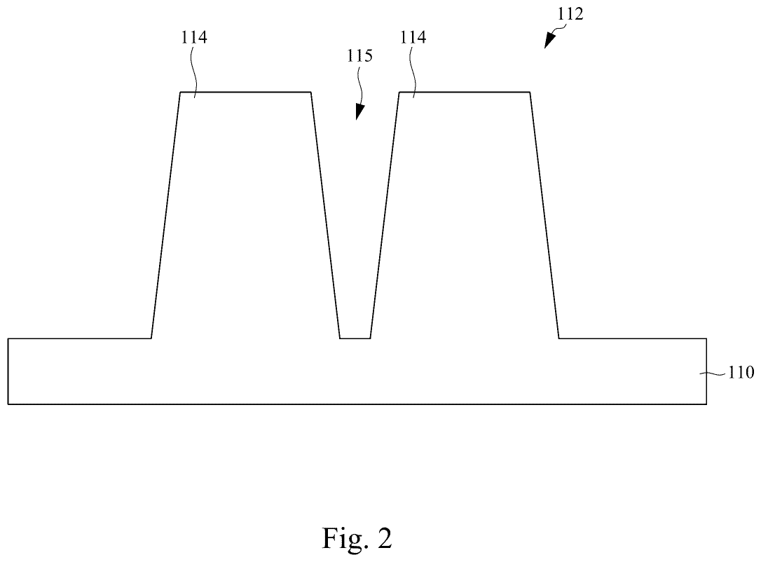

FIG. 2 to FIG. 6 are cross-sectional views of intermediate steps of the manufacturing method of the semiconductor device according to one embodiment of the present disclosure. Refer to FIG. 2, first, etching a substrate 110 to form the active area 112. The etching of the active area 112 can be dry etching, wet etching, a combination thereof, or the like. In FIG. 2, two arrays 114 is shown, but the disclosure is not limited to this. In fact, more arrays 114 can be formed in this step. The arrays 114 formed in this step have the property of large depth to width ratio. In other words, the trench 115 between the two arrays 114 is narrow and deep. In some embodiments, the depth of the trench 115 is in a range of 270 nanometers to 300 nanometers, while the width of the trench 115 is in a range of 2.5 nanometers to 3.5 nanometers. In some embodiments, the width of the array 114 is in a range of 7 nanometers to 13 nanometers.

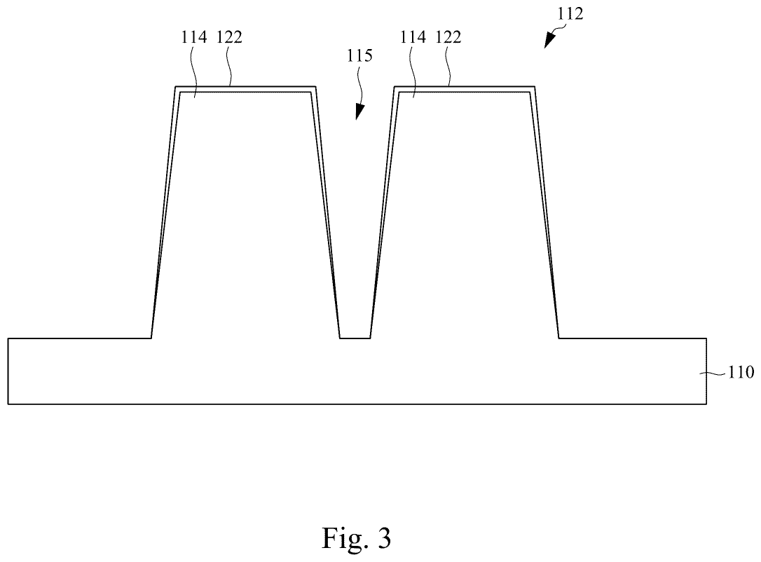

Refer to FIG. 3, thereafter, depositing, using a first atomic layer deposition, a first thin poly silicon layer 122 on the active area 112. The gas used in the first atomic layer deposition includes dichlorosilane (Si₂Cl₂H₂, DCS). During the process, a thin layer of poly silicon will grow on the active area 112. That is, the poly silicon will grow both on the arrays 114 and at the bottom of the trench 115. However, in FIG. 3, the poly silicon at the bottom of the trench 115 is neglected. The function of the first thin poly silicon layer 122 is the seed layer of the poly silicon that will be grown in the process thereafter. In some embodiments, after the first atomic layer deposition, a purge process is performed to clean up the redundant gas. The gas for purging can include nitrogen (N₂), argon (Ar), a combination thereof or other suitable gas.

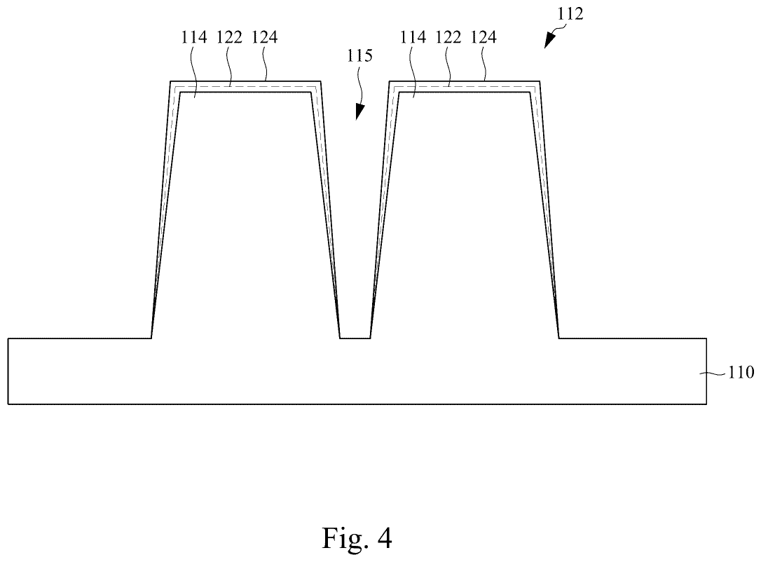

Refer to FIG. 4, thereafter, depositing, using a second atomic layer deposition, a second thin poly silicon layer 124 on the active area 112. The gas used in the second atomic layer deposition includes dichlorosilane (Si₂Cl₂H₂, DCS). During the process, a thin layer of poly silicon will grow on the active area 112. That is, the poly silicon will grow both on the arrays 114 and at the bottom of the trench 115. However, in FIG. 4, the poly silicon at the bottom of the trench 115 is neglected. The function of the second thin poly silicon layer 124 is the seed layer of the poly silicon that will be grown in the process thereafter. In some embodiments, after the first atomic layer deposition, a purge process is performed to clean up the redundant gas. The gas for purging can include nitrogen (N₂), argon (Ar), a combination thereof or other suitable gas.

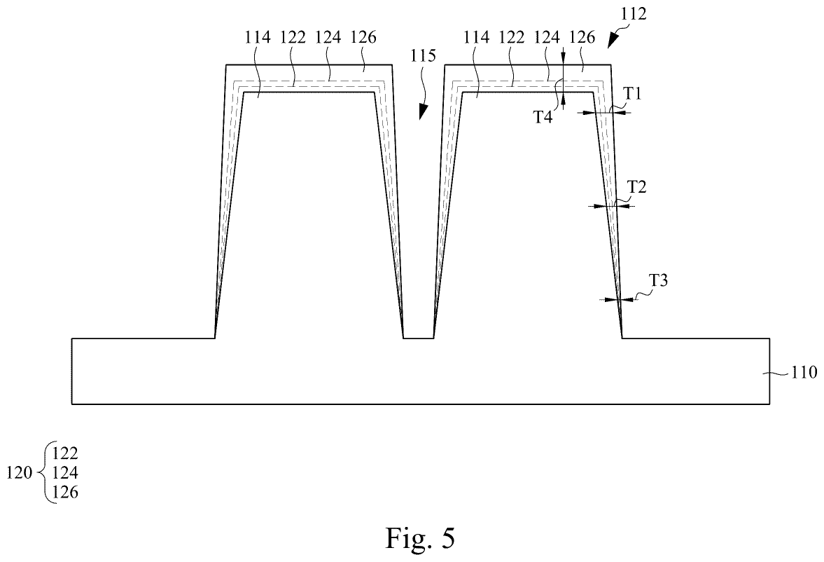

Refer to FIG. 5, thereafter, depositing, using a chemical vapor deposition, a poly silicon layer 126 on the active area 112 to form a poly silicon structure 120, in which a gas for the chemical vapor deposition includes disilane (Si₂H₆), a thickness of the poly silicon layer in a bottom of the trenches 115 is substantially zero. The chemical vapor deposition process uses the first thin poly silicon layer 122 and the second thin poly silicon layer 124 as the seed layer to grow, such that the film grown on the arrays 114 is dense. Since the step coverage of the chemical vapor deposition process with the disilane gas is uneven compared to the previous atomic layer deposition, the thickness of the top portion of the sidewall of the poly silicon structure 120 is greater than the thickness of the bottom portion of the sidewall of the poly silicon structure 120. In some embodiments, a ratio of a thickness T1 of the top portion of the sidewall of the poly silicon structure 120 to a thickness T4 of a top plane of the poly silicon structure 120 is in a range of 0.6 to 0.7. In some embodiments, a ratio of a thickness T2 of a middle portion of a sidewall of the poly silicon structure 120 to a thickness T4 of a top plane of the poly silicon structure 120 is in a range of 0.6 to 0.7. In some embodiments, a ratio of a thickness T3 of a bottom portion of a sidewall of the poly silicon structure 120 to a thickness T4 of a top plane of the poly silicon structure is in a range of 0.35 to 0.45. The thickness of the poly silicon layer on the bottom of the trench 115 is substantially zero.

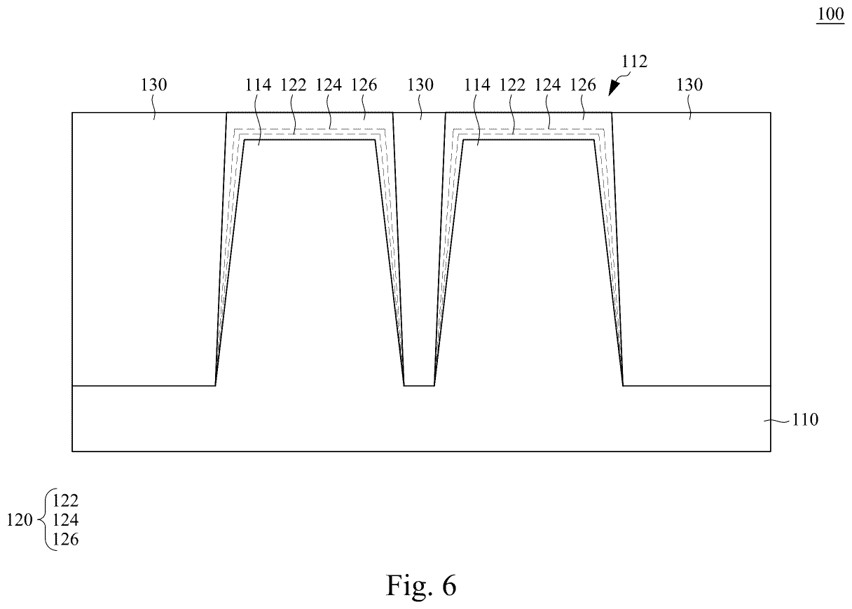

Refer to FIG. 6, thereafter, filling the trench with a dielectric material to form a shallow trench isolation (STI) 130. The function of the shallow trench isolation 130 is to electrically isolate the arrays 114. Since the thickness of the poly silicon layer at the bottom of the trench 115 (see FIG. 5) is substantially zero, there is no risk of short at the bottom of the trench 115, such that the shallow trench isolation 130 can properly isolate the arrays. The dielectric material of the shallow trench isolation 130 can include silicon oxide (SiO₂) or other suitable dielectric material. After this step, the semiconductor device 100 is manufactured.

In summary, since the manufacturing method of the semiconductor device 100 includes a first atomic layer deposition, a second atomic layer deposition and a chemical vapor deposition, the thickness of the poly silicon structure 120 grow by the chemical vapor deposition gradually shrinks from a top portion of a sidewall of the poly silicon structure 120 to a bottom portion of the sidewall of the poly silicon structure 120, which means no poly silicon is grown at the bottom of the trench 115, eliminating the possibility of causing short at the bottom of the trench 115 while enlarging the area of the array 114.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A manufacturing method of a semiconductor device, comprising:
depositing, using a first atomic layer deposition, a first thin poly silicon layer on an active area, wherein the active area comprises a trench;
depositing, using a second atomic layer deposition, a second thin poly silicon layer on the active area; and
depositing, using a chemical vapor deposition, a poly silicon layer on the active area to form a poly silicon structure, wherein a gas for the chemical vapor deposition comprises disilane, a thickness of the poly silicon layer in a bottom of the trenches is substantially zero.

2. The manufacturing method of the semiconductor device of claim 1, further comprising:
etching a substrate to form the active area.

3. The manufacturing method of the semiconductor device of claim 1, further comprising:
filling the trenches with a dielectric material to form a shallow trench isolation.

4. The manufacturing method of the semiconductor device of claim 1, wherein a ratio of a thickness of a top portion of a sidewall of the poly silicon structure to a thickness of a top plane of the poly silicon structure is in a range of 0.6 to 0.7.

5. The manufacturing method of the semiconductor device of claim 1, wherein a ratio of a thickness of a middle portion of a sidewall of the poly silicon structure to a thickness of a top plane of the poly silicon structure is in a range of 0.6 to 0.7.

6. The manufacturing method of the semiconductor device of claim 1, wherein a ratio of a thickness of a bottom portion of a sidewall of the poly silicon structure to a thickness of a top plane of the poly silicon structure is in a range of 0.35 to 0.45.

7. The manufacturing method of the semiconductor device of claim 1, wherein a gas used in the first atomic layer deposition comprises dichlorosilane.

8. A manufacturing method of a semiconductor device, comprising:
depositing, using a first atomic layer deposition, a first thin poly silicon layer on an active area, wherein the active area comprises a trench, a gas used in the first atomic layer deposition comprises dichlorosilane;
depositing, using a second atomic layer deposition, a second thin poly silicon layer on the active area; and
depositing, using a chemical vapor deposition, a poly silicon layer on the active area to form a poly silicon structure, wherein a gas for the chemical vapor deposition comprises disilane.

9. The manufacturing method of the semiconductor device of claim 8, further comprising:
etching a substrate to form the active area.

10. The manufacturing method of the semiconductor device of claim 8, further comprising:
filling the trenches with a dielectric material to form a shallow trench isolation.

11. The manufacturing method of the semiconductor device of claim 8, wherein a ratio of a thickness of a top portion of a sidewall of the poly silicon structure to a thickness of a top plane of the poly silicon structure is in a range of 0.6 to 0.7.

12. The manufacturing method of the semiconductor device of claim 8, wherein a ratio of a thickness of a middle portion of a sidewall of the poly silicon structure to a thickness of a top plane of the poly silicon structure is in a range of 0.6 to 0.7.

13. The manufacturing method of the semiconductor device of claim 8, wherein a ratio of a thickness of a bottom portion of a sidewall of the poly silicon structure to a thickness of a top plane of the poly silicon structure is in a range of 0.35 to 0.45.

14. The manufacturing method of the semiconductor device of claim 8, wherein a gas used in the second atomic layer deposition comprises disilane.

15. A semiconductor device, comprising:
a substrate, wherein the substrate comprises an active area, the active area comprises a trench; and
a poly silicon layer located on the active area, wherein a thickness of the poly silicon layer gradually shrinks from a top portion of a sidewall of the poly silicon layer to a bottom portion of the sidewall of the poly silicon layer.

16. The semiconductor device of claim 15, wherein a thickness of the poly silicon layer on a bottom of the trench is substantially zero.

17. The semiconductor device of claim 15, wherein a ratio of a thickness of the top portion of the sidewall of the poly silicon layer to a thickness of a top plane of the poly silicon layer is in a range of 0.6 to 0.7.

18. The semiconductor device of claim 15, wherein a ratio of a thickness of a middle portion of the sidewall of the poly silicon layer to a thickness of a top plane of the poly silicon layer is in a range of 0.6 to 0.7.

19. The semiconductor device of claim 15, wherein a ratio of a thickness of the bottom portion of the sidewall of the poly silicon layer to a thickness of a top plane of the poly silicon layer is in a range of 0.35 to 0.45.

20. The semiconductor device of claim 15, wherein the poly silicon layer is formed by a first atomic layer deposition, a second atomic layer deposition and a chemical vapor deposition.
